(19) United States
(12) Patent Application Publication
(10) Pub. No.: US 2023/0172070 A1
(43) Pub. Date: Jun. 1, 2023

(54) EXCITATION ELECTRODE, QUARTZ CRYSTAL VIBRATOR ELEMENT, QUARTZ CRYSTAL VIBRATOR, SENSOR, OSCILLATOR, AND METHOD OF MANUFACTURING QUARTZ CRYSTAL VIBRATOR ELEMENT

(71) Applicant: SII Crystal Technology Inc., Chiba-shi (JP)

(72) Inventor: Tomohiro MOMOSE, Chiba-shi (JP)

(21) Appl. No.: 17/987,660

(22) Filed: Nov. 15, 2022

(30) Foreign Application Priority Data
Nov. 26, 2021 (JP) 2021-192562

(51) Int. Cl. H01L 41/047; H01L 41/113; H01L 41/09; H01L 41/293

(52) U.S. Cl. CPC H01L 41/0472; H01L 41/1132; H01L 41/094; H01L 41/293; H03B 5/32

(57) ABSTRACT

There are provided an excitation electrode, a quartz crystal vibrator element, a quartz crystal vibrator, a sensor, an oscillator, and a method of manufacturing a quartz crystal vibrator element which are not affected by heat in a process or a use environment to surely prevent a frequency fluctuation from occurring, reduction in size of which can be achieved, and which are low in cost and excellent in productivity. The excitation electrodes are disposed on an outer surface of a quartz crystal plate, apply an electrical field for exciting the quartz crystal plate to the quartz crystal plate, have a single layer structure formed of a two-dimensional layered substance, and are used when arranged as a pair so as to be opposed to each other via the quartz crystal plate.

### RELATED APPLICATIONS

This application claims priority to Japanese Patent Application No. 2021-192562, filed on Nov. 26, 2021, the entire content of which is incorporated herein by reference.

### BACKGROUND OF THE INVENTION

### 1. Field of the Invention

The present disclosure relates to an excitation electrode, a quartz crystal vibrator element, a quartz crystal vibrator, a sensor, an oscillator, and a method of manufacturing a quartz crystal vibrator element.

### 2. Description of the Related Art

For example, in the past, in an electronic apparatus such as a cellular phone or portable information terminal equipment, there has been used a vibrator using quartz crystal as a device used for a clock time source, a timing source for a control signal and so on, a reference signal source, and so on. As a quartz crystal vibrator of this kind, there has been known, for example, a device having a quartz crystal vibrator element airtightly sealed in a package provided with a cavity.

As such a quartz crystal vibrator element as described above, there can be cited, for example, a device having a configuration provided with a quartz crystal blank having a base part and a pair of vibrating arm parts extending in parallel to each other from the base part, and excitation electrodes disposed on surfaces of the pair of vibrating arm parts (see, e.g., JP-A-2018-129729 (Document 1) and JP-A-2003-017975 (Document 2)).

In the quartz crystal vibrator element, by a voltage being applied to the excitation electrodes, the pair of vibrating arm parts each vibrate with a predetermined resonance frequency in directions of getting closer to and away from each other using base end portions (coupling portions to the base part) as the respective starting points.

In the past, as the excitation electrode to be disposed on the surface of the quartz crystal blank in the quartz crystal vibrator element, there is adopted an electrode in which any one of chromium, nickel, and titanium excellent in adhesiveness as a foundation is used as a contact layer to be disposed between the electrode and the quartz crystal blank, and gold or silver chemically stable is used as a main layer disposed on the contact layer as disclosed in Document 1 and Document 2.

Incidentally, gold and silver used as the main layer of the excitation electrode in the past are each an extremely expensive metal material, and therefore have a problem of significantly affecting a cost of a variety of types of devices such as a quartz crystal vibrator element or a quartz crystal vibrator using the quartz crystal vibrator element.

Further, the metal such as chromium, nickel, and titanium used in the past in the contact layer of the excitation electrode has a problem that alloying with gold or silver constituting the main layer progresses when aging progresses due to the effect of the heat under a use environment, and thus a frequency fluctuation as the vibrator is incurred. Such an effect of the heat particularly has a tendency that the smaller in size the quartz crystal vibrator element is, the more conspicuous the effect becomes, and therefore, becomes an obstacle to further reduction in size of the quartz crystal vibrator element and a variety of types of devices which is required by a market.

The present disclosure is made in view of the problems described above, and has an object of providing an excitation electrode, a quartz crystal vibrator element, a quartz crystal vibrator, a sensor, an oscillator, and a method of manufacturing a quartz crystal vibrator element which are not affected by the heat in the process or the use environment to surely prevent the frequency fluctuation from occurring, the reduction in size of which can be achieved, and which are low in cost and excellent in productivity.

### SUMMARY OF THE INVENTION

In order to solve the problems described above, an excitation electrode, a quartz crystal vibrator element, a quartz crystal vibrator, a sensor, an oscillator, and a method of manufacturing a quartz crystal vibrator element according to the present disclosure adopt configurations described below.

[1] An excitation electrode according to an aspect of the present disclosure is an excitation electrode arranged on an outer surface of a quartz crystal blank, and configured to apply an electrical field for exciting the quartz crystal blank to the quartz crystal blank, the excitation electrode including a single layer structure formed of a two-dimensional layered substance, wherein the excitation electrode is arranged as a pair to be used so as to be opposed to each other via the quartz crystal blank.

According to the present aspect, since the excitation electrode has the single layer structure formed of the two-dimensional layered substance which is thermally and chemically stable, even when being affected by the heat generated during the manufacturing process such as a high-temperature reflow process and the heat under the use environment, the alloying due to metallic diffusion or the like does not occur. Therefore, it is possible to prevent the frequency fluctuation in the quartz crystal vibrator element using the present excitation electrode from occurring. Further, by using the two-dimensional layered substance which is thermally and chemically stable for the excitation electrodes, an increase in aging resistance is also expected.

Further, by configuring the whole of the excitation electrode so as to have the single layer structure formed of the two-dimensional layered substance low in price, it is possible to obtain excellent productivity, and at the same time, reduction in cost becomes possible. Further, since it is possible to reduce the thickness dimension by providing the excitation electrode with the single layer structure formed of the two-dimensional layered substance, it becomes possible to achieve the reduction in size of the quartz crystal vibrator element using the excitation electrode, the quartz crystal vibrator using the quartz crystal vibrator element, and so on, and at the same time, the quartz crystal vibrator element and the quartz crystal vibrator become excellent in impact resistance. Further, since the excitation electrode having the single layer structure is used, and thus there is no need to perform interlayer bonding which is performed in the multilayer electrode, it is possible to prevent a harmful gas from being generated.

Further, since the quartz crystal and the two-dimensional layered substance are similar in crystal structure to each other, the adhesiveness of the excitation electrode to the quartz crystal blank becomes excellent, and the electrical characteristics and the mechanical strength characteristics become excellent.

[2] In the excitation electrode according to the aspect in [1] described above, the two-dimensional layered substance is preferably a single layer film or a multilayer film of graphene including a carbon atom as a chief element.

According to the excitation electrode in the present aspect, since the two-dimensional layered substance is formed of a single layer film or a multilayer film of graphene as a sheet like substance having a hexagonal grid structure constituted by carbon atoms and bonding of the carbon atoms, it is possible to further improve the adhesiveness of the excitation electrode to the quartz crystal blank while surely preventing the frequency fluctuation from occurring as described above, and therefore, the electrical characteristics and the mechanical strength characteristics become more excellent.

[3] In the excitation electrode according to the aspect in [1] described above, it is possible to adopt a configuration in which the two-dimensional layered substance is one of silicene, germanene, stanene, and plumbene.

According to the excitation electrode in the present aspect, by using silicene, germanene, stanene, or plumbene obtained by replacing the carbon atoms in graphene with one of the elements of silicon, germanium, tin, and lead as the two-dimensional layered substance, it is possible to improve the adhesiveness of the excitation electrode to the quartz crystal blank while surely preventing the frequency fluctuation from occurring similarly to the case of using graphene, and therefore, the electrical characteristics and the mechanical strength characteristics become excellent.

[4] In the excitation electrode according to any one of the aspects in [1] through [3] described above, the two-dimensional layered substance is preferably doped with an impurity consisting of a group-XIII element or a group-XV element.

According to the excitation electrode in the present aspect, by the impurity consisting of a group-XIII element or a group-XV element being doped in the two-dimensional layered substance constituting the excitation electrode, it is possible to obtain a film further improved in electrical conductivity. Therefore, it is possible to surely prevent the frequency fluctuation from occurring, and at the same time, it is possible to obtain the extremely excellent electrical characteristics.

[5] In the excitation electrode according to the aspect in [4] described above, the impurity is preferably phosphorus or nitrogen.

According to the excitation electrode in the present aspect, since phosphorus or nitrogen is doped as the impurity into the two-dimensional layered substance constituting the excitation electrode, the film further improved in electrical conductivity is obtained, and therefore, it is possible to surely prevent the frequency fluctuation from occurring, and at the same time, it is possible to obtain the extremely excellent electrical characteristics.

[6] In the excitation electrode according to any one of the aspects in [1] through [5] described above, it is possible to adopt a configuration in which the two-dimensional layered substance has a honeycomb structure having electrical conductivity.

According to the excitation electrode in the present aspect, by providing the two-dimensional layered substance with the honeycomb structure having electrical conductivity, the thermal characteristics, the chemical characteristics, and the electrical characteristics of the two-dimensional layered substance are further stabilized, and at the same time, the mechanical characteristics such as extension or contraction are also improved. Therefore, it is possible to further enhance the adhesiveness of the excitation electrode to the quartz crystal blank while surely preventing the frequency fluctuation from occurring, and therefore, the electrical characteristics and the mechanical strength characteristics become extremely excellent.

[7] In the excitation electrode according to any one of the aspects in [1] through [5] described above, it is possible to adopt a configuration in which the two-dimensional layered substance has a mille-feuille structure having electrical conductivity.

According to the excitation electrode in the present aspect, since the two-dimensional layered substance has the mille-feuille structure having electrical conductivity, the thermal characteristics, the chemical characteristics, and the electrical characteristics of the two-dimensional layered substance are further stabilized similarly to the above. Therefore, it is possible to further enhance the adhesiveness of the excitation electrode to the quartz crystal blank while surely preventing the frequency fluctuation from occurring, and therefore, the electrical characteristics and the mechanical strength characteristics become extremely excellent.

[8] In the excitation electrode according to one of the aspects in [6] and [7] described above, it is possible to adopt a configuration in which the two-dimensional layered substance is a substance exhibiting a metallic or half-metallic band gap structure.

According to the excitation electrode in the present aspect, since the two-dimensional layered substance is formed of the substance exhibiting the metallic or half-metallic band gap structure, the electrical conductivity of the two-dimensional layered substance is improved, and thus, a threshold voltage is reduced. Thus, it is possible to surely prevent the frequency fluctuation from occurring, and at the same time, it is possible to obtain the extremely excellent electrical characteristics.

[9] The quartz crystal vibrator element according to an aspect of the present disclosure includes a quartz crystal blank having a pair of vibrating arm parts, and an electrode film disposed on an outer surface of the quartz crystal blank, wherein the electrode film has a pair of excitation electrodes arranged on outer surfaces of the pair of vibrating arm parts, and the excitation electrodes are the excitation electrode according to any one of the aspects in [1] through [8] described above.

According to the present aspect, since the quartz crystal vibrator element is provided with the excitation electrode according to the present disclosure described above, the alloying of the excitation electrode due to the thermal influence does not occur, and therefore it is possible to prevent the frequency fluctuation from occurring similarly to the above. Further, it is possible to achieve the reduction is size of the whole of the quartz crystal vibrator element, and at the same time, it becomes possible to achieve the reduction in size of the quartz crystal vibrator and so on using the quartz crystal vibrator element.

[10] The quartz crystal vibrator according to an aspect of the present disclosure includes the quartz crystal vibrator element according to the aspect in [9] described above, and a package configured to airtightly seal the quartz crystal vibrator element.

According to the present aspect, since the quartz crystal vibrator is provided with the quartz crystal vibrator element having the excitation electrode according to the present disclosure described above, the alloying of the excitation electrode due to the thermal influence does not occur, and therefore it is possible to prevent the frequency fluctuation from occurring similarly to the above, and the electrical characteristics become excellent, and at the same time, it becomes possible to achieve reduction in size of the whole of the quartz crystal vibrator.

[11] The sensor according to an aspect of the present disclosure is a sensor characterized by using the quartz crystal vibrator according to the aspect in

described above.

According to the present aspect, since the sensor is equipped with the quartz crystal vibrator according to the present disclosure described above, the alloying of the excitation electrode due to the thermal influence in the quartz crystal vibrator element does not occur, and therefore it is possible to prevent the frequency fluctuation from occurring similarly to the above, and the electrical characteristics become excellent, and at the same time, it becomes possible to achieve reduction in size of the whole of the sensor.

[12] The oscillator according to an aspect of the present disclosure includes the quartz crystal vibrator according to the aspect in [10] described above, wherein the quartz crystal vibrator is electrically coupled as an oscillator element to an integrated circuit.

According to the present aspect, since the oscillator is equipped with the quartz crystal vibrator according to the present disclosure described above, the alloying of the excitation electrode due to the thermal influence in the quartz crystal vibrator element does not occur, and therefore it is possible to prevent the frequency fluctuation from occurring similarly to the above, and the electrical characteristics become excellent.

[13] The method of manufacturing the quartz crystal vibrator element according to an aspect of the present disclosure includes an electrode film formation step including an electrode film deposition step of forming an electrode film having a single layer structure formed of a two-dimensional layered substance on an outer surface of a quartz crystal blank having a pair of vibrating arm parts, and a patterning step of patterning the electrode film to thereby form excitation electrodes arranged as a pair on respective outer surfaces of the pair of vibrating arm parts so as to be opposed to each other via the quartz crystal blank.

According to the present aspect, since there is adopted a method of forming the electrode film having the single layer structure formed of the two-dimensional layered substance on the outer surface of the quartz crystal blank in the electrode film deposition step, and then patterning the electrode film in the patterning step to thereby form the excitation electrode arranged as a pair so as to be opposed to each other via the quartz crystal blank, it is possible to simplify the electrode film deposition step, and at the same time, it is possible to reduce the process time. Therefore, it is possible to surely prevent the frequency fluctuation from occurring without being affected by the heat in the process or under the use environment as described above, and it becomes possible to manufacture the quartz crystal vibrator element small in size at low cost and with high productivity.

[14] In the method of manufacturing the quartz crystal vibrator element according to the aspect in [13] described above, in the electrode film deposition step, it is preferable to adopt a method of forming the electrode film on the outer surface of the quartz crystal blank using a chemical vapor deposition (CVD) method or an atomic layer deposition (ALD) method.

According to the method of manufacturing the quartz crystal vibrator element in the present aspect, by forming the electrode film having the single layer structure formed of the two-dimensional layered substance on the outer surface of the quartz crystal blank using the CVD method or the ALD method in the electrode film deposition step, it is possible to form the electrode film excellent in electrical characteristics, adhesiveness to the quartz crystal blank, and mechanical strength characteristics at low cost and with high productivity.

[15] In the method of manufacturing the quartz crystal vibrator element according to one of the aspects in [13] and [14] described above, it is preferable to adopt a method in which in the electrode film deposition step, the electrode film is formed using graphene including a carbon atom as a chief element as the two-dimensional layered substance, and in the patterning step, the electrode film is patterned by forming a resist on the electrode film using a photolithography method, and then removing at least a part of the electrode film using plasma ashing.

According to the method of manufacturing the quartz crystal vibrator element in the present aspect, by adopting the method of forming the electrode film using graphene in the electrode film deposition step, and then forming the resist using the photolithography method and then removing a part of the electrode film using plasma ashing to perform the patterning in the patterning step, it becomes possible to accurately and selectively remove a part of the electrode film thinner than the resist by controlling the ashing condition such as ashing time. Thus, it is possible to form the excitation electrode having a high dimensional accuracy at low cost and with high productivity.

According to the present disclosure, by providing the configurations described above, it is possible to provide an excitation electrode, a quartz crystal vibrator element, a quartz crystal vibrator, a sensor, an oscillator, and a method of manufacturing a quartz crystal vibrator element which are not affected by the heat in the process or the use environment to surely prevent the frequency fluctuation from occurring, the reduction in size of which can be achieved, and which are low in cost and excellent in productivity.

### BRIEF DESCRIPTION OF THE DRAWINGS

FIG. 1 is a plan view for schematically explaining an oscillator equipped with a quartz crystal vibrator having a quartz crystal vibrator element to which an excitation electrode as an embodiment of the present disclosure is applied.

FIG. 2 is a perspective view for schematically explaining the quartz crystal vibrator provided with the quartz crystal vibrator element to which the excitation electrode as the embodiment of the present disclosure is applied.

FIG. 3 is a diagram for schematically explaining the quartz crystal vibrator as the embodiment of the present disclosure, and is a plan view showing a state in which a sealing plate of the quartz crystal vibrator shown in FIG. 2 is detached.

FIG. 4 is a diagram for schematically explaining the quartz crystal vibrator as the embodiment of the present disclosure, and is a cross-sectional view along a line IV-IV shown in FIG. 3.

FIG. 5 is a diagram for schematically explaining the quartz crystal vibrator as the embodiment of the present disclosure, and is a perspective view showing the quartz crystal vibrator shown in FIG. 2 in an exploded manner.

FIG. 6 is a plan view for schematically explaining the quartz crystal vibrator element to which the excitation electrode as the embodiment of the present disclosure is applied.

FIG. 7 is a diagram for schematically explaining the quartz crystal vibrator element to which the excitation electrode as the embodiment of the present disclosure is applied, and is a cross-sectional view along a line VII-VII shown in FIG. 6.

FIG. 8 is a diagram for schematically explaining the quartz crystal vibrator element to which the excitation electrode as the embodiment of the present disclosure is applied, and is a cross-sectional view along a line VIII-VIII shown in FIG. 6.

FIG. 9 is a flowchart for explaining processes provided to a method of manufacturing the quartz crystal vibrator element as the embodiment of the present disclosure.

### DETAILED DESCRIPTION OF THE PREFERRED EMBODIMENTS

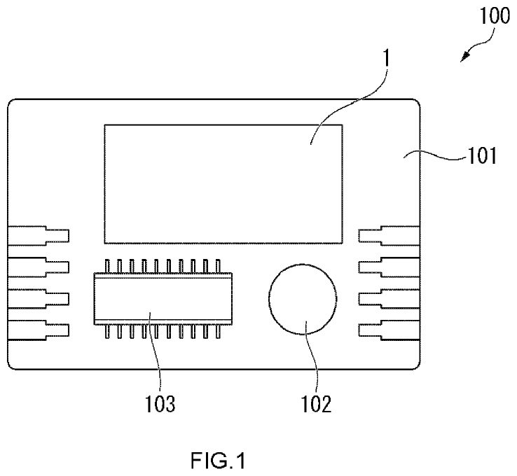

An embodiment of an excitation electrode, a quartz crystal vibrator element, a quartz crystal vibrator, a sensor, an oscillator, and a method of manufacturing the quartz crystal vibrator element according to the present disclosure is hereinafter cited, and configurations thereof will be described with reference to FIG. 1 through FIG. 9 as needed. It should be noted that each of the drawings used in the following description shows a portion to be a feature in an enlarged manner for the sake of convenience in some cases in order to make the feature of the excitation electrode, the quartz crystal vibrator element, the quartz crystal vibrator, the sensor, and the oscillator easy to understand, and dimensional ratio and so on of each of the constituents are different from the real ones in some cases. Further, materials, dimensions, and so on shown as an example in the following explanation are illustrative only, and the present disclosure is not limited thereto, and can be implemented with an arbitrary modification within the scope or the spirit of the present disclosure.

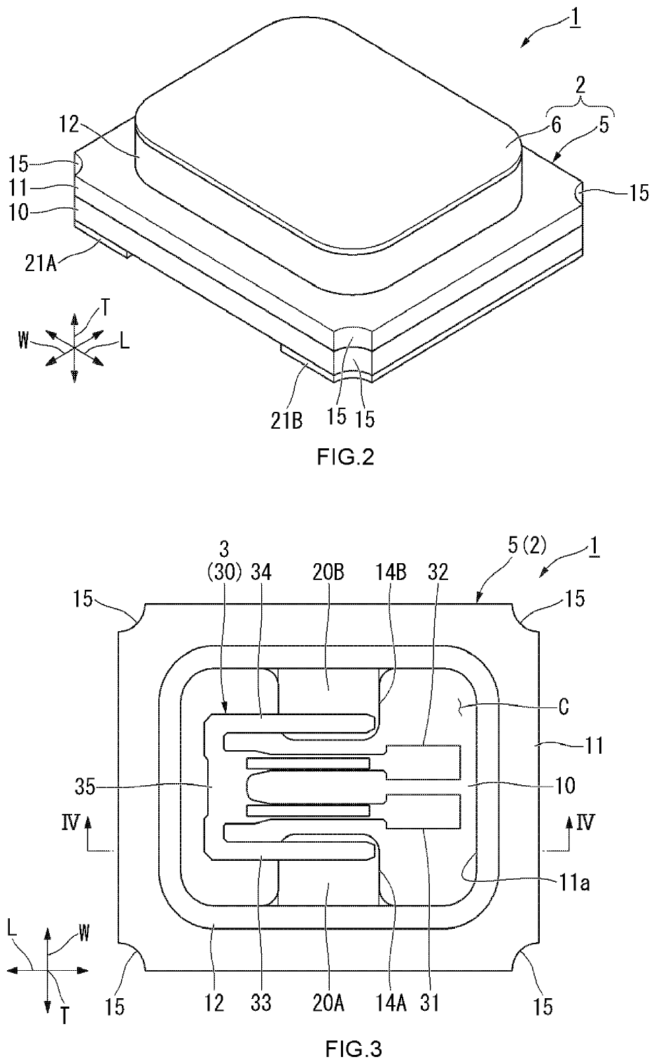

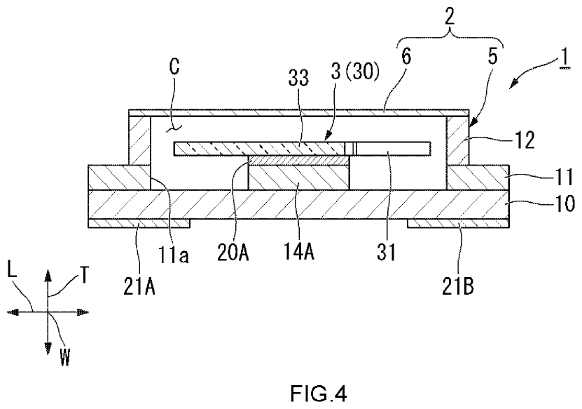

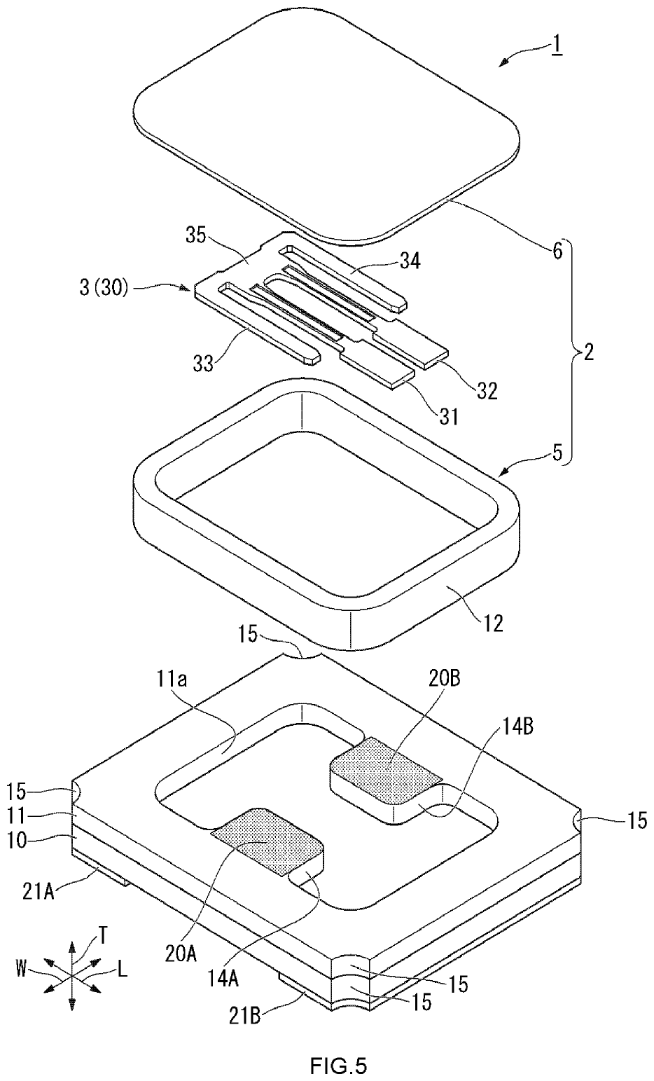

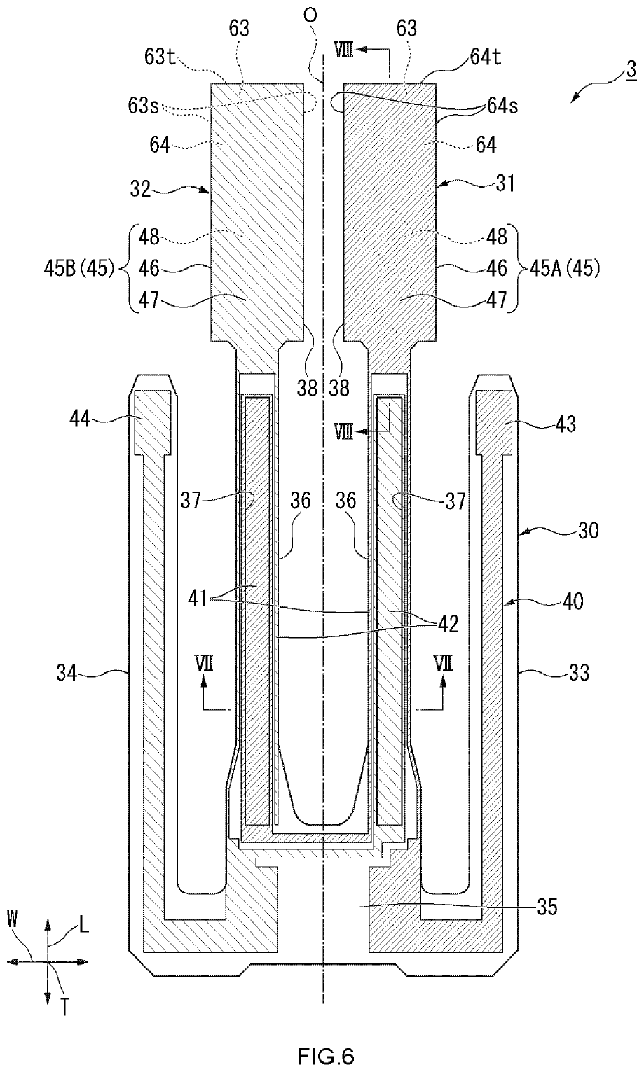

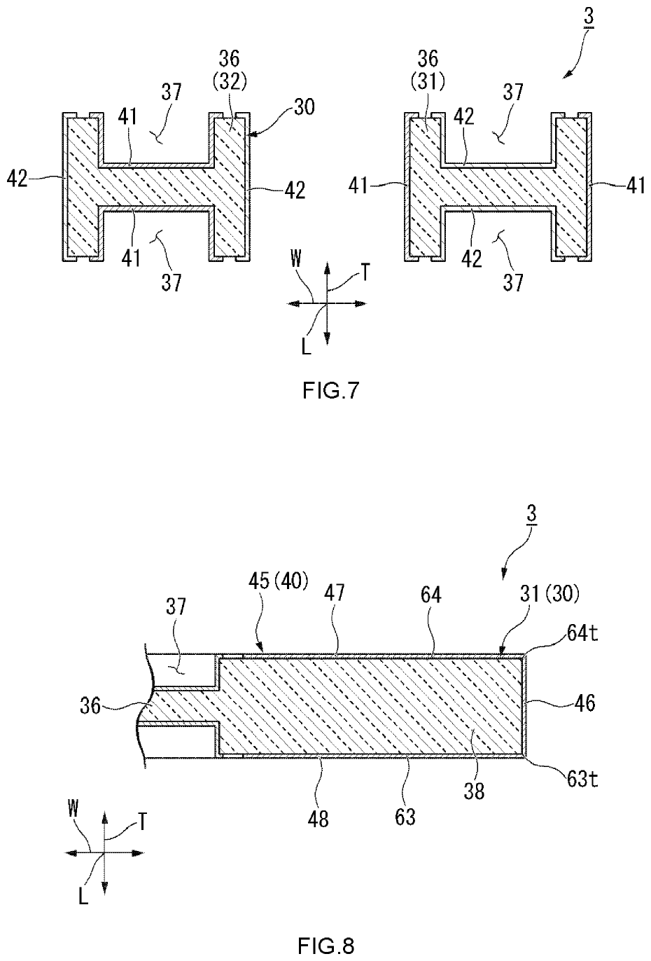

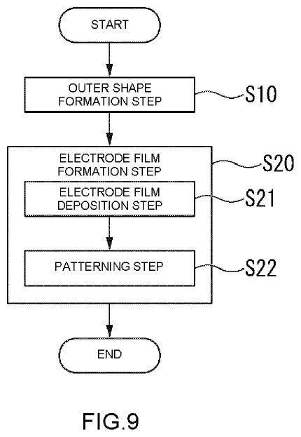

FIG. 1 is a plan view for schematically explaining an oscillator equipped with a quartz crystal vibrator having a quartz crystal vibrator element to which an excitation electrode according to the present embodiment is applied. FIG. 2 is a perspective view showing the quartz crystal vibrator having the quartz crystal vibrator element to which the excitation electrode according to the present embodiment is applied, and FIG. 3 is a plan view showing a state in which a sealing plate of the quartz crystal vibrator shown in FIG. 2 is detached. FIG. 4 is a cross-sectional view along a line IV-IV in the quartz crystal vibrator shown in FIG. 3, and FIG. 5 is a perspective view showing the quartz crystal vibrator shown in FIG. 2 in an exploded manner. FIG. 6 is a plan view showing the quartz crystal vibrator to which the excitation electrode according to the present embodiment is applied, FIG. 7 is a cross-sectional view along a line VII-VII shown in FIG. 6, and FIG. 8 is a cross-sectional view along a line VIII-VIII shown in FIG. 6. Further, FIG. 9 is a flowchart for explaining processes provided to a method of manufacturing the quartz crystal vibrator element according to the present embodiment.

In the following description, constituents having the same or similar functions in the excitation electrode, the quartz crystal vibrator element, the quartz crystal vibrator, the sensor, and the oscillator according to the embodiment will be provided with the same reference symbols, and the description of portions common to those constituents will be omitted in some cases.

Although described later in detail, the excitation electrodes according to the present embodiment correspond to excitation electrodes 41, 42 which are disposed on outer surfaces of a quartz crystal plate (a quartz crystal blank) 30 as shown in FIG. 6 and so on, and which apply an electrical field for exciting the quartz crystal plate 30 to the quartz crystal plate 30. Further, the excitation electrodes 41, 42 according to the present embodiment are each provided with a single-layer structure formed of a two-dimensional layered substance, and are electrodes to be used while being arranged as a pair so as to be opposed to each other via the quartz crystal plate 30.

### <Oscillator>

As shown in FIG. 1, an oscillator 100 according to the present embodiment is generally configured by electrically coupling a quartz crystal vibrator 1, which is provided with a quartz crystal vibrator element 3 to which the excitation electrodes 41, 42 (see FIG. 6 and so on) according to the present embodiment are applied, and which is described later in detail, to an integrated circuit 103 as an oscillator element.

Specifically, the oscillator 100 according to the present embodiment is provided with a board 101, an electronic component 102, an integrated circuit 103, and the quartz crystal vibrator 1.

The electronic component 102 is, for example, a capacitor, and is mounted o the board 101.

The integrated circuit 103 is, for example, a semiconductor circuit for the oscillator, and is mounted on the board 101. The integrated circuit 103 is electrically coupled to each of the quartz crystal vibrator 1 and the electronic component 102 via interconnections not shown.

As described above, the quartz crystal vibrator 1 is provided with the quartz crystal vibrator element 3 to which the excitation electrodes 41, 42 according to the present embodiment are applied, and is mounted, for example, in the vicinity of the integrated circuit 103 on the board 101, and functions as the oscillator element in the oscillator 100 according to the present embodiment.

The excitation electrodes 41, 42, the quartz crystal vibrator element 3, and the quartz crystal vibrator 1 according to the present embodiment will be described later in detail.

It should be noted that at least a part of the oscillator 100 according to the present embodiment can arbitrarily be molded with resin not shown.

In the oscillator 100, when the quartz crystal vibrator 1 is supplied with the power, the quartz crystal vibrator element 3 (see FIGS. 3, 5) of the quartz crystal vibrator 1 vibrates. The vibration of the quartz crystal vibrator element 3 is converted into an electric signal by a piezoelectric characteristic provided to the quartz crystal vibrator element 3. The electric signal is output from the quartz crystal vibrator 1 to the integrated circuit 103. The integrated circuit 103 executes a variety of types of processing on the electric signal output from the quartz crystal vibrator 1 to thereby generate a frequency signal.

The oscillator 100 can be applied to, for example, a single-function oscillator for a timepiece, a timing control device for controlling an operation timing of a variety of devices such as a computer, and a device for providing time, a calendar, or the like.

It should be noted that the integrated circuit 103 described above is configured in accordance with a function required to the oscillator 100, and can include a so-called an RTC (real-time clock) module.

Since the oscillator 100 according to the present embodiment is provided with the quartz crystal vibrator 1 including the quartz crystal vibrator element 3 to which the excitation electrodes 41, 42 according to the present embodiment described later in detail are applied, the alloying of the excitation electrodes 41, 42 (see FIG. 6) caused by the thermal influence in the quartz crystal vibrator element 3 does not occur, and it is possible to prevent the frequency fluctuation from occurring, and thus, the oscillator 100 becomes excellent in electrical characteristics.

### <Quartz Crystal Vibrator (Including Quartz Crystal Vibrator Element Having Excitation Electrodes)>

As shown in FIG. 2 through FIG. 5, the quartz crystal vibrator 1 according to the present embodiment is a surface mount type vibrator of a so-called ceramic package type. The quartz crystal vibrator 1 is generally configured including a package 2 incorporating a cavity C sealed airtightly, and the quartz crystal vibrator element 3 housed in the cavity C. The quartz crystal vibrator 1 in the illustrated example is provided with an outer shape of a substantially rectangular solid shape.

It should be noted that in the present embodiment, in the plan view, a longitudinal direction of the quartz crystal vibrator 1 is referred to as a longitudinal direction L, a direction along the shorter dimension thereof is referred to as a width direction W, and a direction perpendicular to the longitudinal direction L and the width direction W is referred to as a thickness direction T.

The package 2 has a package main body 5, and a sealing plate 6 which is bonded to the package main body 5, and at the same time, forms the cavity C between the sealing plate 6 and the package main body 5.

The package main body 5 has a first base substrate 10 and a second base substrate 11 bonded to each other in an overlapping state, and a sealing ring 12 bonded on the second base substrate 11.

As the first base substrate 10, there is used a substrate which is made of ceramics, and exhibits a rectangular shape in a plan view viewed from the thickness direction T. An upper surface of the first base substrate 10 constitutes a bottom portion of the cavity C. On the lower surface of the first base substrate 10, there are formed a pair of external electrodes 21A, 21B at a distance in the longitudinal direction L. The external electrodes 21A, 21B are each formed of a single layer film made of single metal or a laminated film having different metals stacked on one another formed by, for example, vapor deposition or sputtering.

The second base substrate 11 is a substrate which is made of ceramics, and the outer shape in the plan view of which is made the same as that of the first base substrate 10, and is integrally bonded in a state of being stacked on the first base substrate 10 by a method such as sintering.

Here, as the ceramic material used for each of the first and second base substrates 10, 11, there can be used, for example, HTCC (High Temperature Co-Fired Ceramic) made of alumina, LTCC (Low Temperature Co-Fired Ceramic) made of glass ceramics, and so on.

As shown in FIG. 3 through FIG. 5, the second base substrate 11 is provided with a penetrating part 11a penetrating the second base substrate 11 in the thickness direction T. The penetrating part 11a exhibits a rectangular shape with rounded corners in the plan view. Further, in an inner side surface of the penetrating part 11a, in portions located on both sides in the width direction W, there are respectively formed mounting parts 14A, 14B protruding inward in the width direction W. It should be noted that the mounting parts 14A, 14B are each located in a central portion in the longitudinal direction L in the second base substrate 11.

On the mounting parts 14A, 14B, there are respectively formed a pair of electrode pads 20A, 20B which are coupling electrodes to the quartz crystal vibrator element 3. Similarly to the external electrodes 21A, 21B described above, the electrode pads 20A, 20B are each formed of a single layer film made of single metal or a laminated film having different metals stacked on one another formed by, for example, vapor deposition or sputtering. The electrode pads 20A, 20B and the external electrodes 21A, 21B are electrically coupled to each other, respectively, via respective through interconnections not shown penetrating the first base substrate 10 and the second base substrate 11 in the thickness direction T.

On the four corners of each of the first and second base substrates 10, 11, there are formed cutout parts 15 each having a quarter-arc shape in the plan view throughout the entire length in the thickness direction T of the first and second base substrates 10, 11. The first and second base substrates 10, 11 are manufactured by bonding two ceramic substrates in, for example, a wafer state so as to be stacked on one another, then forming a plurality of through holes penetrating both of the ceramic substrates so as to be arranged in a matrix, and then cutting both of the ceramic substrates in a grid manner with reference to the through holes. On this occasion, since each of the through holes is divided into four parts, the cutout parts 15 described above are formed.

The sealing ring 12 is a conductive frame-like member one size smaller than the outer shape of each of the first and second base substrates 10, 11, and is bonded to the upper surface of the second base substrate 11. Specifically, the sealing ring 12 is bonded on the second base substrate 11 by baking with a brazing material such as silver solder, a soldering material, or the like, or bonded by fusion bonding to a metal bonding layer formed on the second base substrate 11. The sealing ring 12 constitutes the sidewall of the cavity C together with the inner side surface of the second base substrate 11 (the penetrating part 11a). In the illustrated example, the inner side surface of the sealing ring 12 is disposed so as to be coplanar with the inner side surface of the second base substrate 11.

As the material of the sealing ring 12, there can be cited, for example, a nickel base alloy, and more specifically, it is sufficient to arbitrarily be selected from a group consisting of Kovar, elinvar, invar, 42-alloy, and so on. In particular, as the material of the sealing ring 12, it is preferable to select a material close in thermal expansion coefficient to the first and second base substrates 10, 11 made of ceramics. For example, when using alumina having a thermal expansion coefficient of 6.8×10^{-6/}° C. as the first and second base substrates 10, 11, Kovar having a thermal expansion coefficient of 5.2×10⁻⁶/° C. or 42-alloy having a thermal expansion coefficient of 4.5 through 6.5×10⁻⁶/° C. is preferably used as the sealing ring 12.

The sealing plate 6 is formed of an electrically-conductive substrate, and is bonded on the sealing ring 12 to airtightly seal the inside of the package main body 5. Further, a space zoned by the sealing ring 12, the sealing plate 6, and the first and second base substrates 10, 11 constitutes the cavity C airtightly sealed.

The quartz crystal vibrator element 3 is housed in the cavity C of the package 2 sealed airtightly. The quartz crystal vibrator element 3 is provided with the quartz crystal plate 30 formed of quartz crystal. The quartz crystal plate 30 has a pair of vibrating arm parts 31, 32 and a pair of support arm parts 33, 34.

The quartz crystal vibrator element 3 is installed in the package 2 by the support arms parts 33, 34 being supported by the mounting parts 14A, 14B of the package 2 with an electrically-conductive adhesive not shown inside the cavity C. Thus, the quartz crystal vibrator element 3 is supported in a state in which the vibrating arm parts 31, 32 are floating from the base substrates 10, 11 inside the cavity C. On outer surfaces of the vibrating arm parts 31, 32, there are respectively disposed two systems of excitation electrodes 41, 42 (see FIG. 6) for vibrating the pair of vibrating arm parts 31, 32 when a predetermined voltage is applied.

When making the quartz crystal vibrator 1 operate, first, a predetermined voltage is applied to the external electrodes 21A, 21B (see FIG. 2). Then, a current flows through the excitation electrodes 41, 42, and thus, an electrical field is generated between the excitation electrodes 41, 42. The pair of vibrating arm parts 31, 32 vibrate with a predetermined resonance frequency in, for example, directions (along the width direction W) of getting closer to and away from each other due to the inverse piezoelectric effect caused by the electrical field generated between the excitation electrodes 41, 42. Further, the vibration of the vibrating arm parts 31, 32 can be used as the time source, the timing source of a control signal, the reference signal source, and so on.

Since the quartz crystal vibrator 1 according to the present embodiment is provided with the quartz crystal vibrator element 3 to which the excitation electrodes 41, 42 according to the present embodiment described later in detail are applied, the alloying of the excitation electrodes 41, 42 (see FIG. 6) caused by the thermal influence in the quartz crystal vibrator element 3 does not occur, and it is possible to prevent the frequency fluctuation from occurring, and thus it becomes possible to make the quartz crystal vibrator 1 excellent in electrical characteristics, and at the same time, to achieve reduction in size of the whole of the quartz crystal vibrator 1.

### [Quartz Crystal Vibrator Element (Including Excitation Electrodes)]

The quartz crystal vibrator element 3 which constitutes the quartz crystal vibrator 1 according to the present embodiment described above, and which is provided with the excitation electrodes 41, 42 will hereinafter be described in detail.

As shown in FIG. 6, the quartz crystal vibrator element 3 according to the present embodiment is provided with the quartz crystal plate 30, and electrode films 40 disposed on an outer surface including obverse and reverse surfaces of the quartz crystal plate 30.

It should be noted that a longitudinal direction, a width direction, and a thickness direction of the quartz crystal vibrator element 3 respectively coincide with the longitudinal direction L, the width direction W, and the thickness direction T of the quartz crystal vibrator 1 according to the present embodiment described above. Therefore, in the following description related to the quartz crystal vibrator element 3, the detail description is presented using the longitudinal direction L, the width direction W, and the thickness direction T of the quartz crystal vibrator 1 similarly to the above.

### (Quartz Crystal Plate)

The quartz crystal plate 30 is provided with a base part 35, the pair of vibrating arm parts 31, 32 (the first vibrating arm part 31 and the second vibrating arm part 32) extending in the longitudinal direction L from the base part 35, and the pair of support arm parts 33, 34 (the first support arm part 33 and the second support arm part 34) located at both sides in the width direction W with respect to the base part 35. The quartz crystal plate 30 is formed so that the planar shape viewed from the thickness direction T is substantially symmetrical about the central axis 0 along the longitudinal direction L.

The first vibrating arm part 31 and the second vibrating arm part 32 are arranged side by side in the width direction W in parallel to each other. The first and second vibrating arm parts 31, 32 vibrate in the directions (along the width direction W) of getting closer to and away from each other each using the base end at the base part 35 side as the fixed end, and the tip as the free end. Each of the first and second vibrating arm parts 31, 32 has a main body part 36 extending from the base end toward the tip of corresponding one of the first and second vibrating arm parts 31, 32, and a weight part 38 located at the tip of corresponding one of the first and second vibrating arm parts 31, 32.

As shown in FIG. 6 and FIG. 7, the main body part 36 is provided with groove parts 37. The groove parts 37 are recessed in the thickness direction T, and at the same time extend along the longitudinal direction L on both principal surfaces of the main body part 36. The groove parts 37 are each formed continuously from the vicinity of the base end of corresponding one of the first and second vibrating arm parts 31, 32 to the vicinity of the tip of the main body part 36.

As shown in FIG. 6, the weight parts 38 each extend in the longitudinal direction L from the tip portion of the main body part 36. The weight part 38 has a rectangular planar shape, and is formed to be wider in the width direction W than the main body part 36. Thus, it becomes possible to increase the mass of each of the tip parts in the first and second vibrating arm parts 31, 32, and inertial moment when vibrating, and it is possible to decrease the length of the first and second vibrating arm parts 31, 32 compared to a quartz crystal vibrator element not provided with the weight parts 38.

The first and second support arm parts 33, 34 are each formed to have an L shape in the plan view, and are arranged so as to surround the base part 35 and the first and second vibrating arm parts 31, 32 (the main body parts 36) from the outer sides in the width direction W. Specifically, the first and second support arm parts 33, 34 respectively protrude from the both end surfaces in the width direction W in the base part 35 outward in the width direction W, and then extend along the longitudinal direction L in parallel to the first and second vibrating arm parts 31, 32, respectively. Here, the first support arm part 33 is disposed at the same side as the first vibrating arm part 31 with respect to the central axis O. Further, the second support arm part 34 is disposed at the same side as the second vibrating arm part 32 with respect to the central axis O.

### (Electrode Films: Electrode Films Including Excitation Electrodes)

The electrode films 40 are constituted by the excitation electrodes 41, 42, mounting electrodes 43, 44, and coupling interconnections 45.

The excitation electrodes 41, 42 are disposed on the outer surfaces of the main body parts 36 of the vibrating arm parts 31, 32 in two systems. The excitation electrodes 41, 42 are patterned on the outer surfaces of the main body parts 36 so as to electrically be isolated from each other. The excitation electrodes 41, 42 according to the present embodiment are constituted by the first excitation electrode 41 and the second excitation electrode 42. Out of these electrodes, the first excitation electrode 41 is formed on both side surfaces facing to the width direction W in the main body part 36 of the first vibrating arm part 31, and on the groove parts 37 of the second vibrating arm part 32. Further, the second excitation electrode 42 is formed on the groove parts 37 of the first vibrating arm part 31, and on both side surfaces of the main body part 36 of the second vibrating arm part 32.

These excitation electrodes 41, 42 respectively vibrate the first and second vibrating arm parts 31, 32 in the width direction W when the predetermined drive voltage is applied between the excitation electrodes 41, 42.

It should be noted that in the present embodiment, the first excitation electrode 41 and the second excitation electrode 42 are simply referred to as excitation electrodes 41, 42 in some cases for the sake of convenience of explanation.

The mounting electrodes 43, 44 are disposed as a mounting part used when mounting the quartz crystal vibrator element 3 on the package 2. The mounting electrodes 43, 44 are respectively disposed on principal surfaces (reverse surfaces) in the tip portions of the first and second support arm parts 33, 34. Specifically, the mounting electrodes 43, 44 consist of a first mounting electrode 43 disposed on the first support arm part 33, and a second mounting electrode 44 disposed on the second support arm part 34. Among these electrodes, the first mounting electrode 43 is electrically coupled to the first excitation electrode 41. Further, the second mounting electrode 44 is electrically coupled to the second excitation electrode 42. These mounting electrodes 43, 44 are electrically coupled to the electrode pads 20A, 20B of the package 2, respectively, via the electrically-conductive adhesive.

Coupling interconnections 45A, 45B couple the excitation electrodes 41 to each other, and couple the excitation electrodes 42 to each other at the tip side in the first and second vibrating arm parts 31, 32, respectively. The coupling interconnections 45 consist of the first coupling interconnection 45A coupled to the first excitation electrodes 41, and the second coupling interconnection 45B coupled to the second excitation electrodes 42. Among these, the first coupling interconnection 45A electrically couples the first excitation electrodes 41 on the both side surfaces of the first vibrating arm part 31 to each other. Further, the second coupling interconnection 45B electrically couples the second excitation electrodes 42 on the both side surfaces of the second vibrating arm part 32 to each other.

It should be noted that the first coupling interconnection 45A and the second coupling interconnection 45B are formed to have respective shapes and sizes similar to each other, and are therefore referred to simply as the coupling interconnections 45 when the first coupling interconnection 45A and the second coupling interconnection 45B are not distinguished from each other in the following description.

Each of the coupling interconnections 45 has a side part 46, an obverse part 47, and a reverse part 48. The side part 46 is disposed on the entire end surface of each of the first and second vibrating arm parts 31, 32 at the tip side of the groove parts 37 in each of the first and second vibrating arm parts 31, 32. It should be noted that the end surface is a surface for coupling the principal surfaces to each other, and includes a tip surface facing to the longitudinal direction L, and side surfaces facing to the width direction W. The obverse part 47 is disposed on an obverse surface 64 of each of the first and second vibrating arm parts 31, 32 at the tip side of the groove parts 37 in each of the first and second vibrating arm parts 31, 32. Further, the obverse part 47 is disposed at a distance in the longitudinal direction L from the excitation electrodes 41, 42. Further, the obverse part 47 extends so as to straddle a boundary between the main body part 36 and the weight part 38 in each of the first and second vibrating arm parts 31, 32. Further, a side edge of the obverse part 47 is coupled to the side part 46. The reverse part 48 is disposed on a reverse surface 63 of each of the first and second vibrating arm parts 31, 32 at the tip side of the groove parts 37 in each of the first and second vibrating arm parts 31, 32. The reverse part 48 is disposed at a distance in the longitudinal direction L from the excitation electrodes 41, 42. Further, the reverse part 48 extends so as to straddle a boundary between the main body part 36 and the weight part 38 in each of the first and second vibrating arm parts 31, 32. Further, a side edge of the reverse part 48 is coupled to the side part 46.

As shown in FIG. 6 and FIG. 8, the reverse part 48 of each of the coupling interconnections 45 is arranged so as to cover the entire reverse surface 63 in each of the first and second vibrating arm parts 31, 32. In the illustrated example, the reverse part 48 is formed so as to cover a tip edge 63t of the reverse surface 63 in each of the first and second vibrating arm parts 31, 32, and a pair of side edges 63s extending from the tip edge 63t toward a base end of each of the first and second vibrating arm parts 31, 32.

The obverse part 47 of each of the coupling interconnections 45 is arranged so as to cover the entire obverse surface 64 in each of the first and second vibrating arm parts 31, 32. In the illustrated example, the obverse part 47 is formed so as to cover a tip edge 64t of the obverse surface 64 in each of the first and second vibrating arm parts 31, 32, and a pair of side edges 64s extending from the tip edge 64t toward a base end of each of the first and second vibrating arm parts 31, 32.

It should be noted that although the detailed illustration is omitted in FIG. 6 and FIG. 8, the reverse part 48 and the obverse part 47 of each of the coupling interconnections 45 are formed at a distance so as not to electrically short by providing a slight gap at a position in the vicinity of the tip edge 63t or the tip edge 64t.

Then, as described above, the excitation electrodes 41, 42 according to the present embodiment are each provided with a single-layer structure formed of a two-dimensional layered substance, and are electrodes to be used while being arranged as a pair so as to be opposed to each other via the quartz crystal plate 30. In other words, the excitation electrodes 41, 42 according to the present embodiment are each provided with a structure constituted only by a main layer formed of the two-dimensional layered substance. Further, the “two-dimensional layered substance” described in the present embodiment means a substance taking the two-dimensional structure at the atomic level.

As described above, since the excitation electrodes 41, 42 according to the present embodiment are used while being arranged so as to sandwich the quartz crystal plate 30 with the pair of excitation electrodes 41, 42, it is possible to configure the quartz crystal vibrator element to be used for a so-called AT vibrator.

As described above, since the excitation electrodes 41, 42 are each the excitation electrode having a single layer structure formed of the two-dimensional layered substance which is thermally and chemically stable, even when being affected by the heat generated during the manufacturing process such as a high-temperature reflow process and the heat under the use environment (including a stock under a high-temperature environment) and so on, the alloying due to metallic diffusion or the like occurring in the excitation electrode having the related-art multilayer structure does not occur. Thus, there can be obtained an advantage that it is possible to prevent the frequency fluctuation in the quartz crystal vibrator element 3 using the excitation electrodes 41, 42 from occurring. Further, by using the two-dimensional layered substance which are thermally and chemically stable for the excitation electrodes 41, 42, an increase in aging resistance is also expected.

Further, by configuring the whole of the excitation electrodes 41, 42 so as to have the single layer structure formed of the two-dimensional layered substance low in price without using expensive noble metal, it is possible to obtain excellent productivity, and at the same time, reduction in cost becomes possible. Further, since it is possible to reduce the thickness dimension by providing the excitation electrodes 41, 42 with the single layer structure formed of the two-dimensional layered substance, it becomes possible to achieve the reduction in size of the quartz crystal vibrator element 3 using the excitation electrodes 41, 42, the quartz crystal vibrator 1 using the quartz crystal vibrator element 3, and so on, and at the same time, the quartz crystal vibrator element 3 and the quartz crystal vibrator 1 become excellent in impact resistance. Further, since the excitation electrodes 41, 42 having the single layer structure are used, and thus there is no need to perform interlayer bonding which is performed in the multilayer electrode, it is possible to prevent a harmful gas from being generated, and it is possible to realize a safe manufacturing process.

Further, since the quartz crystal and the two-dimensional layered substance are similar in crystal structure to each other, the adhesiveness of the excitation electrodes 41, 42 to the quartz crystal plate 30 becomes good, and thus, electrical characteristics and mechanical strength characteristics of the quartz crystal vibrator element 3 to be obtained are further improved.

In the excitation electrodes 41, 42 according to the present embodiment, a substance using, for example, a single layer film or a multilayer film of graphene having a carbon atom as a chief element can be adopted as the two-dimensional layered substance which is thermally and chemically stable as described above. Graphene is a sheet-like substance having a hexagonal grid structure constituted by carbon atoms and bonding of the carbon atoms.

In other words, the excitation electrodes 41, 42 according to the present embodiment have the single layer structure formed of the two-dimensional layered substance which does not include a metal layer such as a contact layer, and at the same time, it is possible to use the single layer film or the multilayer film of graphene described above for the two-dimensional layered substance itself.

As described above, by using the single layer film or the multilayer film of graphene as the two-dimensional layered substance constituting the excitation electrodes 41, 42, it is possible to further improve the adhesiveness of the excitation electrodes 41, 42 to the quartz crystal plate 30 while surely preventing the frequency fluctuation from occurring, and therefore, the electrical characteristics and the mechanical strength characteristics become more excellent.

Further, the two-dimensional layered substance constituting the excitation electrodes 41, 42 is not limited to graphene described above, and it is possible to use any one of, for example, silicene, germanene, stanene, and plumbene.

Among the above, silicene is a graphene-like substance which is obtained by replacing the carbon atoms of graphene described above with the silicon element, and which has a grid-like crystal structure.

Germanene is a graphene-like substance which is obtained by replacing the carbon atoms of graphene described above with the germanium element, and which has a grid-like crystal structure.

Stanene is a graphene-like substance which is obtained by replacing the carbon atoms of graphene described above with the tin element, and which has a grid-like crystal structure.

Further, plumbene is a graphene-like substance which is obtained by replacing the carbon atoms of graphene described above with the lead element, and which has a grid-like crystal structure.

In the present embodiment, by using any one of silicene, germanene, stanene, and plumbene as the graphene-like substances described above as the two-dimensional layered substance constituting the excitation electrodes 41, 42, the excitation electrodes 41, 42 become thermally and chemically stable similarly to the case of using graphene, and therefore, it is possible to surely prevent the frequency fluctuation from occurring. Further, similarly to the case of using graphene as the two-dimensional layered substance, since the adhesiveness of the excitation electrodes 41, 42 to the quartz crystal plate 30 is further improved, the electrical characteristics and the mechanical strength characteristics become more excellent.

Further, it is preferable to dope an impurity formed of a group-XIII element or a group-XV element adjacent to a group-XIV element to the two-dimensional layered substance constituting the excitation electrodes 41, 42. By the impurity of the element described above being doped in the two-dimensional layered substance constituting the excitation electrodes 41, 42, it is possible to obtain a film further improved in electrical conductivity. Thus, it is possible to surely prevent the frequency fluctuation from occurring, and at the same time, it is possible to further improve the electrical characteristics.

As the group-XIII element or the group-XV element to be doped in the two-dimensional layered substance constituting the excitation electrode 41, 42 described above, there can be cited, for example, phosphorus (P) or nitrogen (N). In particular, when using graphene as the two-dimensional layered substance, by doping nitrogen located next to carbon (C) on the periodic table into the two-dimensional layered substance, carbon is easily replaced with nitrogen, which is preferable.

The structure of the two-dimensional layered substance constituting the excitation electrodes 41, 42 is not particularly limited, but it is possible to adopt a substance having a honeycomb structure having electrical conductivity like a substance such as graphene illustrated above. The honeycomb structure described in the present embodiment means a structure tightly arranging, for example, regular hexagons or regular hexagonal columns, and is a structure capable of reducing the material necessary to form the film without losing the strength.

As described above, by providing the two-dimensional layered substance constituting the excitation electrodes 41, 42 with the honeycomb structure having electrical conductivity, the thermal characteristics, the chemical characteristics, and the electrical characteristics of the two-dimensional layered substance are further stabilized, and at the same time, the mechanical characteristics such as extension or contraction are also improved. Thus, it is possible to further enhance the adhesiveness of the excitation electrodes 41, 42 to the quartz crystal plate 30 while surely preventing the frequency fluctuation from occurring, and therefore, it becomes possible to further improve the electrical characteristics and the mechanical strength characteristics.

Further, the structure of the two-dimensional layered substance constituting the excitation electrodes 41, 42 is not limited to the honeycomb structure described above, and can be what has, for example, a mille-feuille structure having electrical conductivity. The mille-feuille structure described in the present embodiment means, for example, a stacked structure with a hard layer in which atoms are strongly bonded to each other and a soft layer in which atoms are relatively weakly bonded to each other.

Also when using what has the mille-feuille structure having electrical conductivity for the two-dimensional layered substance constituting the excitation electrodes 41, 42 as described above, similarly to the case of the honeycomb structure described above, it is possible to obtain the advantage that the thermal characteristics, the chemical characteristics, and the electrical characteristics of the two-dimensional layered substance are further stabilized. Thus, similarly to the above, it is possible to further enhance the adhesiveness of the excitation electrodes 41, 42 to the quartz crystal plate 30 while surely preventing the frequency fluctuation from occurring, and therefore, it becomes possible to further improve the electrical characteristics and the mechanical strength characteristics.

Further, in the excitation electrodes 41, 42 according to the present embodiment, such a two-dimensional layered substance in the honeycomb structure or the mille-feuille structure having electrical conductivity as described above can be a substance exhibiting a metallic or half-metallic band gap structure. As described above, by adopting the substance exhibiting the metallic or half-metallic band gap structure as the two-dimensional layered substance constituting the excitation electrodes 41, 42, the electrical conductivity of the two-dimensional layered substance is improved, and thus, a threshold voltage is reduced. Therefore, similarly to the above, it is possible to surely prevent the frequency fluctuation from occurring, and at the same time, it is possible to obtain the extremely excellent electrical characteristics.

It should be noted that in the present embodiment, as long as the excitation electrodes 41, 42 have the single layer structure formed of such a two-dimensional layered substance as described above, structures and materials of other electrodes constituting the electrode films 40, namely the first and second mounting electrodes 43, 44 and the coupling interconnections 45, are not limited. Therefore, as the first and second mounting electrodes 43, 44 and the coupling interconnections 45 described above, it is possible to use, for example, a laminated film obtained by stacking gold (Au) on chromium (Cr) as a foundation layer, which is known to the public.

Incidentally, it is preferable to use what has the single layer structure formed of the two-dimensional layered substance as the first and second mounting electrodes 43, 44 and the coupling interconnections 45 similarly to the excitation electrodes 41, 42 from the viewpoint that the electrical characteristics and the mechanical strength characteristics of the whole of the electrode films 40 are improved, and the whole of the electrode films 40 can be formed in the same step to thereby enhance the productivity and at the same time reduce the manufacturing cost.

Further, it is possible for the excitation electrodes 41, 42 according to the present embodiment to be adopted in a variety of types of vibrators which are used when arranged inside a vacuum package such as a piezoelectric vibrator.

It should be noted that in the present embodiment, the description is presented citing the example in which the excitation electrodes 41, 42 having the single layer structure formed of the two-dimensional layered substance are applied to the quartz crystal vibrator element 3 of the tuning-fork type (a side-arm type) shown in FIG. 6 and so on, but the quartz crystal vibrator element to which the excitation electrodes 41, 42 according to the present embodiment can be applied is not limited to such an example. The excitation electrodes 41, 42 according to the present embodiment can also be applied to a quartz crystal vibrator element having a shape other than in the illustrated example.

Further, the vibrator to which the excitation electrodes 41, 42 according to the present embodiment can be applied is not limited to the quartz crystal vibrator element 3 using such quartz crystal as described above, but the excitation electrodes 41, 42 according to the present embodiment can also be applied to a piezoelectric vibrator element using, for example, alumina (AlN) or lead zirconate titanate (PZT).

### <Sensor>

By using the quartz crystal vibrator 1 including the quartz crystal vibrator element 3 to which the excitation electrodes 41, 42 according to the present embodiment described above are applied, it is possible to configure a variety of sensors.

As such sensors which can be configured using the quartz crystal vibrator 1, there can be cited, for example, a pressure sensor, an acceleration sensor, a tilt sensor, a gyro sensor, a temperature sensor, a biosensor, a mass sensor, and a strain sensor although not shown in the drawings.

As described above, by configuring a variety of sensors using the quartz crystal vibrator 1 according to the present embodiment, since the alloying of the excitation electrodes 41, 42 caused by the thermal influence in the quartz crystal vibrator element 3 does not occur, and thus, the frequency fluctuation can be prevented from occurring, the excellent electrical characteristics can be obtained similarly to the above, and at the same time, it becomes possible to achieve reduction in size of the whole of the sensor.

### <Method of Manufacturing Quartz Crystal Vibrator Element (Including Method of Manufacturing Excitation Electrodes)>

A method of manufacturing the quartz crystal vibrator element 3 having the excitation electrodes 41, 42 according to the present embodiment will hereinafter be described with reference to a flowchart shown in FIG. 9 as needed, and with reference to FIG. 6 through FIG. 8 regarding the details of the constituents similarly to the above.

The method of manufacturing the quartz crystal vibrator element 3 having the excitation electrodes 41, 42 according to the present embodiment is a method of manufacturing such a quartz crystal vibrator element 3 as shown in FIG. 6, and is a method provided with an electrode formation step (S20) including at least the steps described in (1), (2) below as shown in the flowchart in FIG. 9.

(1) An electrode film deposition step (S21) of forming the electrode films 40 having the single layer structure formed of the two-dimensional layered substance on the outer surfaces of the quartz crystal plate 30 having the pair of vibrating arm parts 31, 32.

(2) A patterning step (S22) of patterning the electrode films 40 to thereby form the excitation electrodes 41, 42 arranged as a pair on the outer surfaces of the pair of vibrating arm parts 31, 32 so as to be opposed to each other via the quartz crystal plate 30.

It should be noted that in the manufacturing method according to the present embodiment, description will be presented citing a method as an example in which all of the electrodes constituting the electrode films 40, namely the mounting electrodes 43, 44 and the coupling interconnections 45, are formed to have the single layer structure formed of the two-dimensional layered substance similarly to the excitation electrodes 41, 42, and are formed at the same time in the electrode film deposition step (S21).

In the manufacturing method according to the present embodiment, first, an outer shape formation step (S10) is performed.

In the outer shape formation step (S10), a quartz crystal wafer is curved out to thereby form the quartz crystal plate 30 as the quartz crystal blank.

On this occasion, first, a mask having a shape corresponding to the planar shape of the quartz crystal plate 30 is formed on the surface of the quartz crystal wafer using a photolithography technology.

Then, by performing wet-etching processing on the quartz crystal wafer, the area not masked in the quartz crystal wafer is selectively removed, and the quartz crystal wafer is formed to have the planar shape of the quartz crystal plate 30 having the first and second vibrating arm parts 31, 32 and so on as shown in FIG. 6.

Subsequently, in the outer shape formation step (S10), the groove parts 37 are further formed on the both principal surfaces (the obverse and reverse surfaces) of the first and second vibrating arm parts 31, 32.

Specifically, masks each having a shape corresponding to the shape of the groove part 37 are formed on the both principal surfaces of the quartz crystal wafer using the photolithography technology.

Then, using the wet-etching processing, half etching is performed on the quartz crystal wafer to the extent that the groove part 37 does not penetrate the wafer. Thus, the quartz crystal plate 30 having the groove parts 37 is formed.

Subsequently, the electrode film formation step (S20) is performed.

In the electrode film formation step (S20), the electrode films 40 are disposed on the obverse and reverse surfaces of the quartz crystal plate 30. The electrode film formation step (S20) provided to the manufacturing method according to the present embodiment includes the electrode film deposition step (S21) of forming the electrode films 40 having the single layer structure formed of the two-dimensional layered substance on the outer surfaces of the quartz crystal plate 30, and the patterning step (S22) of forming the excitation electrodes 41, 42 arranged as a pair on the outer surfaces of each of the pair of vibrating arm parts 31, 32 so as to be opposed to each other via the quartz crystal plate 30 by patterning the electrode films 40 as described above.

In the electrode film deposition step (S21), the electrode films 40 having the single layer structure formed of the two-dimensional layered substance are formed on the obverse and reverse surfaces and the end surface of the quartz crystal plate 30 using, for example, a chemical vapor deposition (CVD) method or an atomic layer deposition (ALD) method.

Then, in the patterning step (S22), masks made of a resist material and having shapes corresponding to the outer shapes of the two systems of the excitation electrodes 41, 42, the first and second mounting electrodes 43, 44, and the first and second coupling interconnections 45A, 45B are formed on the outer surfaces of the quartz crystal plate 30.

Subsequently, etching processing is performed on the electrode films 40 to selectively remove the electrode films 40 in the areas which are not masked with the resist. Thus, the excitation electrodes 41, 42, the first and second mounting electrodes 43, 44, and the first and second coupling interconnections 45A, 45B are formed on the outer surfaces of the quartz crystal plate 30.

In the manufacturing method according to the present embodiment, it is more preferable to adopt a method of forming the electrode films 40 using graphene having carbon atoms as the chief element as the two-dimensional layered substance in the electrode film deposition step (S21), and then removing at least a part of the electrode films 40 with plasma ashing to thereby pattern the electrode films 40 in the patterning step (S22). The plasma ashing is a method of, for example, reacting a gas obtained by turning the oxygen gas into a plasma with non-ionizing radiation such as a visible ray and a removal target with each other to gasify the removal target to thereby remove the removal target.

As described above, by adopting the method of removing a part of the electrode films 40 formed of graphene by plasma ashing to thereby perform the patterning, it becomes possible to accurately and electively remove a part of the electrode films thinner than the resist by controlling the ashing condition such as ashing time. Thus, it becomes possible to form the excitation electrodes 41, 42 having a high dimensional accuracy at low cost and with high productivity.

Due to the steps described hereinabove, it is possible to obtain the quartz crystal vibrator element 3 provided with the excitation electrodes 41, 42 shown in FIG. 6.

According to the method of manufacturing the quartz crystal vibrator 1 provided with the excitation electrodes 41, 42 related to the present embodiment, since the excitation electrodes 41, 42 arranged as a pair so as to be opposed to each other via the quartz crystal plate 30 are formed by forming the electrode films 40 having the single layer structure formed of the two-dimensional layered substance on the outer surfaces of the quartz crystal plate 30 in the electrode film deposition step (S21), and then patterning the electrode films 40 in the patterning process (S22) as described above, it is possible to simplify the electrode film deposition step (S21), and at the same time, it is possible to shorten the process time. Therefore, it is possible to surely prevent the frequency fluctuation from occurring without being affected by the heat in the process or under the use environment as described above, and it becomes possible to manufacture the quartz crystal vibrator element 3 small in size at low cost and with high productivity.

Further, according to the manufacturing method related to the present embodiment, by forming the electrode films 40 having the single layer structure formed of the two-dimensional layered substance on the outer surfaces of the quartz crystal plate 30 using the CVD method or the ALD method in the electrode film deposition step (S21), it becomes possible to form the electrode films 40 excellent in electrical characteristics, adhesiveness to the quartz crystal plate 30, and mechanical strength characteristics at low cost and with high productivity.

Further, according to the manufacturing method related to the present embodiment, by adopting a method of forming the electrode films 40 using graphene in the electrode deposition step (S21), then forming the resist using the photolithography method and then performing patterning by removing a part of the electrode films 40 formed of graphene using the plasma ashing in the patterning step (S22), it becomes possible to form the excitation electrodes 41, 42 having the high dimensional accuracy at low cost and with high productivity.

<Other Aspects of Present Disclosure>

The preferred embodiment of the present disclosure is hereinabove described in detail, but the present disclosure is not limited to such a specific embodiment as described above, and there can be adopted a variety of deformations, replacements, and modifications within the scope or the spirit of the present disclosure set forth in the appended claims.

As described above, the excitation electrode according to the present disclosure is not affected by the heat in the process or under the use environment, and capable of surely preventing the frequency fluctuation from occurring, and is capable of achieving the reduction in size, and at the same time, low in cost, and excellent in productivity. Therefore, the quartz crystal vibrator element to which the excitation electrode according to the present disclosure is applied, the quartz crystal vibrator equipped with the quartz crystal vibrator element, the sensor and the oscillator equipped with the quartz crystal vibrator are extremely suitable as a device to be used for a time source, a timing source of a control signal and so on, a reference signal source or the like in an electronic apparatus such as a cellular phone or personal digital assistance equipment.

What is claimed is:

1. An excitation electrode arranged on an outer surface of a quartz crystal blank, and configured to apply an electrical field for exciting the quartz crystal blank to the quartz crystal blank, the excitation electrode comprising:
a single layer structure formed of a two-dimensional layered substance, wherein
the excitation electrode is arranged as a pair to be used so as to be opposed to each other via the quartz crystal blank.

2. The excitation electrode according to claim 1, wherein
the two-dimensional layered substance is a single layer film or a multilayer film of graphene including a carbon atom as a chief element.

3. The excitation electrode according to claim 1, wherein
the two-dimensional layered substance is one of silicene, germanene, stanene, and plumbene.

4. The excitation electrode according to claim 1, wherein
the two-dimensional layered substance is doped with an impurity consisting of a group-XIII element or a group-XV element.

5. The excitation electrode according to claim 4, wherein
the impurity is phosphorus or nitrogen.

6. The excitation electrode according to claim 1, wherein
the two-dimensional layered substance has a honeycomb structure having electrical conductivity.

7. The excitation electrode according to claim 1, wherein
the two-dimensional layered substance has a mille-feuille structure having electrical conductivity.

8. The excitation electrode according to claim 6, wherein
the two-dimensional layered substance is a substance exhibiting a metallic or half-metallic band gap structure.

9. The excitation electrode according to claim 7, wherein
the two-dimensional layered substance is a substance exhibiting a metallic or half-metallic band gap structure.

10. A quartz crystal vibrator element comprising:
a quartz crystal blank having a pair of vibrating arm parts; and
an electrode film disposed on an outer surface of the quartz crystal blank, wherein
the electrode film has a pair of excitation electrodes arranged on outer surfaces of the pair of vibrating arm parts, and
the excitation electrodes are the excitation electrode according to

1.

11. A quartz crystal vibrator comprising:
the quartz crystal vibrator element according to claim 10; and
a package configured to airtightly seal the quartz crystal vibrator element.

12. A sensor comprising:
the quartz crystal vibrator according to claim 11.

13. An oscillator comprising:
the quartz crystal vibrator according to claim 11, wherein
the quartz crystal vibrator is electrically coupled as an oscillator element to an integrated circuit.

14. A method of manufacturing a quartz crystal vibrator element, comprising:
an electrode film formation step including
an electrode film deposition step of forming an electrode film having a single layer structure formed of a two-dimensional layered substance on an outer surface of a quartz crystal blank having a pair of vibrating arm parts, and
a patterning step of patterning the electrode film to thereby form excitation electrodes arranged as a pair on respective outer surfaces of the pair of vibrating arm parts so as to be opposed to each other via the quartz crystal blank.

15. The method of manufacturing the quartz crystal vibrator element according to claim 14, wherein
in the electrode film deposition step, the electrode film is formed on the outer surface of the quartz crystal blank using a chemical vapor deposition (CVD) method or an atomic layer deposition (ALD) method.

16. The method of manufacturing the quartz crystal vibrator element according to claim 14, wherein
in the electrode film deposition step, the electrode film is formed using graphene including a carbon atom as a chief element as the two-dimensional layered substance, and
in the patterning step, the electrode film is patterned by forming a resist on the electrode film using a photolithography method, and then removing at least a part of the electrode film using plasma ashing.
